(19) United States
(12) Patent Application Publication
(10) Pub. No.: US 2023/0352623 A1
(43) Pub. Date: Nov. 2, 2023

(54) SEMICONDUCTOR EPITAXY STRUCTURE AND MANUFACTURING METHOD THEREFOR, AND LED CHIP

(71) Applicant: XIAMEN CHANGELIGHT CO., LTD., Xiamen (CN)

(72) Inventors: Zhiwei LIN, Xiamen (CN); Kaixuan CHEN, Xiamen (CN); Jianjiu CAI, Xiamen (CN); Xiangjing ZHUO, Xiamen (CN); Gang YAO, Xiamen (CN); Wei CHENG, Xiamen (CN)

(73) Assignee: XIAMEN CHANGELIGHT CO., LTD., Xiamen (CN)

(21) Appl. No.: 18/216,575

(22) Filed: Jun. 29, 2023

Related U.S. Application Data
(63) Continuation of application No. PCT/CN2021/079179, filed on Mar. 5, 2021.
Application No. PCT/CN2021/079179 is a continuation of application No. PCT/CN2021/079037, filed on Mar. 4, 2021.

(30) Foreign Application Priority Data
Jan. 4, 2021 (CN) 202110001937.0
Feb. 7, 2021 (CN) 202110177793.4

(51) Int. Cl. H01L 33/14; H01L 33/04; H01L 33/32

(52) U.S. Cl. CPC H01L 33/145; H01L 33/04; H01L 33/32

(57) ABSTRACT

The present disclosure provides a semiconductor epitaxial structure and a manufacturing method therefor, and an LED chip. The semiconductor epitaxial structure may include a substrate, an N-type semiconductor layer, a gate elimination layer, an active layer and a P-type semiconductor layer are sequentially stacked on a surface of a substrate. Furthermore, the gate elimination layer comprises an N-type doped semiconductor layer.

### CROSS-REFERENCE TO RELATED APPLICATION

This application is based upon and claims priority to PCT Application No. PCT/CN2021/079179 filed on Mar. 5, 2021, which claims priority to Chinese Patent Application No. 202110001937.0, filed on Jan. 4, 2021, and to PCT Application PCT/CN/2021/079037 filed on Mar. 4, 2021, which claims priority to Chinese Patent Application No 0.202110177793.4, filed on Feb. 7, 2021, the entire contents of which are incorporated herein by reference for all purposes.

### TECHNICAL FIELD

The present disclosure relates to the field of light-emitting diodes, in particular to a semiconductor epitaxial structure, a manufacturing method thereof, and an LED chip.

### BACKGROUND

A Light Emitting Diode (LED) is a semiconductor electronic component that can emit light. LED has the advantages of high efficiency, long life, small size, low power consumption, etc., and can be used in indoor and outdoor white light lighting, screen display, backlight, and other fields. In the development of the LED industry, gallium nitride (GaN)-based materials are typical representatives of Group V-III compound semiconductors, and improving the photoelectric performance of GaN-based LEDs has become the key to the semiconductor lighting industry.

Epitaxial wafers are the primary products in the LED manufacturing process. The existing GaN-based LED epitaxial wafer includes a substrate, an N-type semiconductor layer, an active layer and a P-type semiconductor layer. The substrate is used to provide a growth surface for epitaxial materials, the N-type semiconductor layer is used to provide electrons for composite light emission, the P-type semiconductor layer is used to provide holes for composite light emission, and the active layer is used for radiation of electrons and holes Composite glow.

However, on the one hand, due to the presence of functional layers with uneven thickness during the crystallization process, the N-type semiconductor layer and the P-type semiconductor layer are interlaced to form a thyristor; on the other hand, in the doping process of each functional layer, due to the low temperature and high doping content, it is easy to cause the thyristor effect. The appearance of the thyristor will increase the turn-on voltage (i.e., dead zone voltage) of the LED, making it difficult for the LED to be lit.

In addition, the internal quantum efficiency of the LED structure has a decisive impact on its brightness and luminous efficiency. However, due to the bipolar input of carriers, electrons and holes are concentrated near the N-type doped region and the P-type doped region respectively. In the quantum wells of the quantum wells, the carriers are unevenly distributed among the quantum wells, especially for the holes with low mobility and high effective mass, this unevenness is more obvious. In addition, due to the inherent polarization effect of GaN-based materials, the probability of transition is reduced, and the probability of carrier radiation recombination is reduced.

At present, the preparation technology of blue-green LEDs is relatively mature. The output wavelength of LEDs using InGaN-based multi-quantum wells can be changed by changing the width and composition of the InGaN-based multi-quantum well structure, the number of quantum wells or the thickness and composition of the barrier layer part to adjust. Traditional InGaN-based multi-quantum well structure light-emitting diodes, due to the influence of built-in polarization electric field and other factors, the probability of radiative recombination of carriers in the InGaN-based multi-quantum well structure is low, and the internal quantum of light emitted by the InGaN-based multi-quantum well structure low efficiency leads to low luminous efficiency of light emitting diodes based on the InGaN-based multi-quantum well structure.

### SUMMARY

The present disclosure provides a semiconductor epitaxial structure, a manufacturing method, and a LED chip thereof to solve the problems caused by the thyristor effect in the LED chip.

According to a first aspect, the present disclosure provides a semiconductor epitaxial structure including a substrate, an N-type semiconductor layer, a gate elimination layer, an active layer, and a P-type semiconductor layer are sequentially stacked on the surface of the substrate. furthermore, the gate elimination layer may include an N-type doped semiconductor layer.

According to a second aspect, the present disclosure provides an LED chip including a semiconductor epitaxial structure according to the first aspect, an N-type electrode that is in ohmic contact with the N-type semiconductor layer, and a P-type electrode that is in ohmic contact with the P-type semiconductor layer.

According to a third aspect, the present disclosure provides a method for manufacturing a semiconductor epitaxial structure. The method may include: providing a substrate and sequentially growing an N-type semiconductor layer, a gate elimination layer, a shallow well layer, an active layer, and a P-type semiconductor layer on the surface of the substrate.

### BRIEF DESCRIPTION OF THE DRAWINGS

In order to more clearly illustrate the technical solutions in the embodiments of the present disclosure or the prior art, the following will briefly introduce the drawings that need to be used in the description of the embodiments or the prior art. Obviously, the accompanying drawings in the following description are only embodiment of the present disclosure, and those skilled in the art can also obtain other drawings according to the provided drawings without creative work.

FIG. 1 is a schematic structural diagram of a semiconductor epitaxial structure in accordance with some examples of the present disclosure.

FIG. 2 is a schematic diagram of variation of the N-type doping concentration with the thickness of the gate elimination layer in accordance with some examples of the present disclosure.

FIGS. 3-10 are schematic diagrams showing variation of the N-type doping concentration of the gate elimination layer with the thickness in accordance with some examples of the present disclosure.

FIG. 11 is a schematic structural diagram of a semiconductor epitaxial structure in accordance with some examples of the present disclosure.

FIG. 12 is a schematic structural diagram of the last potential barrier layer and the last potential well layer in the active region in accordance with some examples of the present disclosure.

FIG. 13 is a schematic diagram of growth temperature relationship of each layer in the active region in accordance with some examples of the present disclosure.

### DETAILED DESCRIPTION

Embodiments of the present disclosure will be described in detail in the following descriptions, examples of which are shown in the accompanying drawings, in which the same or similar elements and elements having same or similar functions are denoted by like reference numerals throughout the descriptions. The embodiments described herein with reference to the accompanying drawings are explanatory and illustrative, which are used to generally understand the present disclosure. The embodiments shall not be construed to limit the present disclosure. Based on the embodiments of the present disclosure, all other embodiments obtained by persons of ordinary skill in the art without making creative efforts belong to the protection scope of the present disclosure.

Terms used in the present disclosure are merely for describing specific examples and are not intended to limit the present disclosure. The singular forms “one,” “the,” and “this” used in the present disclosure and the appended claims are also intended to include a multiple form, unless other meanings are clearly represented in the context. It should also be understood that the term “and/or” used in the present disclosure refers to any or all of possible combinations including one or more associated listed items.

Reference throughout the present disclosure to “one embodiment,” “an embodiment,” “an example,” “some embodiments,” “some examples,” or similar language means that a particular feature, structure, or characteristic described is included in at least one embodiment or example. Features, structures, elements, or characteristics described in connection with one or some embodiments are also applicable to other embodiments, unless expressly specified otherwise.

It should also be noted that in present disclosure, relational terms such as first and second etc. are only used to distinguish one entity or operation from another entity or operation, and do not necessarily require or imply that these entities or operations any such actual relationship or order exists between. Moreover, the term “comprises,” “includes” or any other variation thereof is intended to cover a non-exclusive inclusion such that an article or device comprising a set of elements includes not only those elements, but also other elements not expressly listed, or also include elements inherent in the article or device. Without further limitations, an element defined by the phrase “comprising a . . . ” does not exclude the presence of additional identical elements in an article or device comprising the aforementioned element.

Each embodiment in the present disclosure is described in a progressive manner, each embodiment focuses on the difference from other embodiments, and the same and similar parts of each embodiment can be referred to each other.

The description of present disclosure is provided to enable any person skilled in the art to make or use the present application. Various modifications to these embodiments will be readily apparent to those skilled in the art, and the general principles defined herein may be implemented in other embodiments without departing from the spirit or scope of the present disclosure. Therefore, the present disclosure will not be limited to the embodiments or examples shown herein but is to be accorded the widest scope consistent with the principles and novel features disclosed herein.

In some examples, the present disclosure provides a semiconductor epitaxial structure, including: the substrate 110; the N-type semiconductor layer 140, the gate elimination layer 150, the active layer 170, and the P-type semiconductor layer 190 are sequentially stacked on the surface of the substrate 110; and the gate elimination layer 150 that includes an N-type doped semiconductor layer, as shown in FIG. 1.

In some examples, the gate elimination layer 150 may include a non-uniform N-type doped semiconductor layer.

In some examples, the type of the substrate 110 is not limited in the semiconductor epitaxial structure as shown in the figures of the present disclosure. For example, the substrate 110 may be but not limited to a sapphire substrate, a silicon substrate, and the like. In addition, the specific material types of the N-type semiconductor layer 140, the active layer 170, and the P-type semiconductor layer 190 may be but not be limited in the semiconductor epitaxial structure of the examples discussed in the present disclosure. For example, the N-type semiconductor layer may be but not limited to gallium nitride layer. Correspondingly, the P-type semiconductor layer may be, but not limited to, a gallium nitride layer.

In some examples, the N-type doping concentration of the gate elimination layer 150 gradually increases or decreases along a first direction or changes in a gradient. The highest doping concentration of the gate elimination layer 150 along the first direction may be greater than that of the N-type semiconductor layer 140. The first direction is perpendicular to the substrate 110 and the first direction is from the substrate 110 to the N-type semiconductor layer 140.

In some examples, a shallow well layer is provided between the gate elimination layer 150 and the active layer 170, and the shallow well layer may include multiple sub-shallow well layers 160 stacked in sequence along the first direction.

In some examples, the number of sub-shallow well layers 160 may be two, but this is not a limitation of the present disclosure.

In some examples, a lattice constant of each sub-shallow well layer 160 increases along the first direction, and the lattice constant of a sub-shallow well layer 160 that is adjacent to the active layer 170 is lower/smaller than a lattice constant of the active layer 170. In some examples, the energy band of the sub-shallow well layer 160 decreases along the first direction, and the energy band of the sub-shallow well layer 160 that is adjacent to the active layer 170 is higher/greater than the energy band of the active layer 170.

In some examples, each sub-shallow well layer 160 is composed of an alternate cycle of a potential barrier layer 161 and a potential well layer 162, and the lattice constant of the gate elimination layer 150 is smaller than the potential well layer 162 of the first sub-shallow well layer 160 along the first direction. The energy band of the elimination gate layer 150 is greater than the energy band of the potential well layer 162 of the first sub-shallow well layer 160 along the first direction.

In some examples, sub-shallow well layers 160 are formed by alternate cycles of potential barrier layers and potential well layers, and the band gap energy of the potential well layers is lower than that of the potential barrier layers.

In some examples, the N-type doping concentration of the gate elimination layer 5 is 1×10¹⁷˜1×10²⁰ cm⁻³.

In some examples, the gate elimination layer 150 includes an N-type doped GaN layer or an AlGaN layer or an AlGaInN layer or a GaInN layer or an AlInN layer.

In some examples, the number of one or more sub-shallow well layers 160 is 1-20, including the endpoint values.

In some examples, the thickness of the gate elimination layer 5 does not exceed 100 nm.

In some examples, at least a buffer layer 120 and an unintentionally doped layer 130 are provided sequentially along the first direction between the substrate 110 and the N-type semiconductor layer 140.

In some examples, an electron blocking layer 180 is further provided between the active layer 170 and the P-type semiconductor layer 190.

In some examples, the present disclosure also provides a method for manufacturing a semiconductor epitaxial structure as shown in FIG. 1. The method includes the following steps:

Step S101, providing a substrate 110;

Step S102, sequentially growing an N-type semiconductor layer 140, a gate elimination layer 150, a shallow well layer, an active layer 170, and a P-type semiconductor layer 190 on the surface of the substrate 110, where the gate elimination layer 150 includes an N-type doped semiconductor layer.

In some examples, the gate elimination layer 150 includes a non-uniform N-type doped semiconductor layer.

In some examples, the N-type doping concentration of the gate elimination layer 150 gradually increases or decreases gradually along the first direction, or changes or varies in a gradient. The first direction is perpendicular to the substrate 110, and is directed from the substrate 110 to the N-type semiconductor layer 140.

In some examples, the shallow well layer includes several sub-shallow well layers 160 stacked in sequence along the first direction, the lattice constant of each sub-shallow well layer 160 increases along the first direction, and the lattice constant of the sub-shallow well layer 160 adjacent to the active layer 170 is lower/smaller than that of the active layer 170. The energy band of each sub-shallow well layer 160 decreases along the first direction, and the energy band of the sub-shallow well layer 160 adjacent to the active layer 170 is higher/greater than the energy band of the active layer 170.

Moreover, in the sallow well layer, potential barrier layers and potential well layers may be arranged in an alternating manner. For example, as shown in FIG. 1, each sub-shallow well layer 160 is composed of alternating cycle/s of potential barrier layers 161 and potential well layers 162, and the lattice constant of the gate elimination layer is smaller than the lattice constant of the potential well layers 162 of the first sub-shallow well layer 160 along the first direction, the energy band of the gate elimination layer is greater than the energy band of the potential well layer 162 of the first sub-shallow well layer 160 along the first direction.

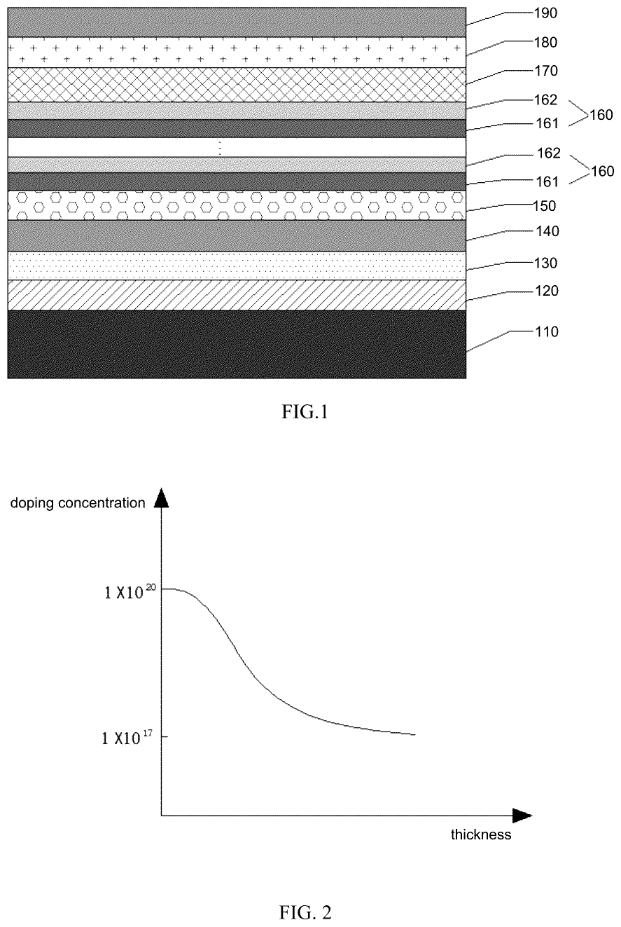

FIG. 2 is a schematic diagram showing the variation of N-type doping concentration with the thickness of the gate elimination layer provided by the present disclosure, wherein the abscissa represents the thickness, and the ordinate represents the N-type doping concentration.

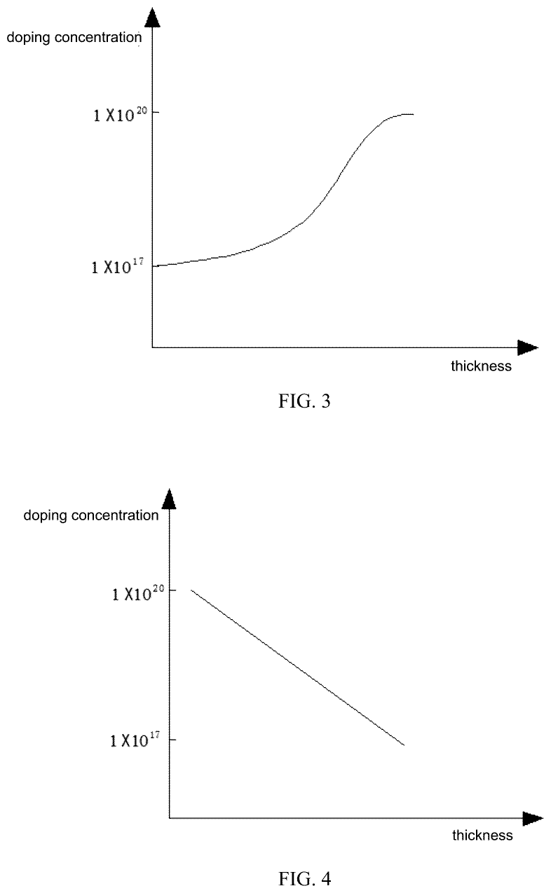

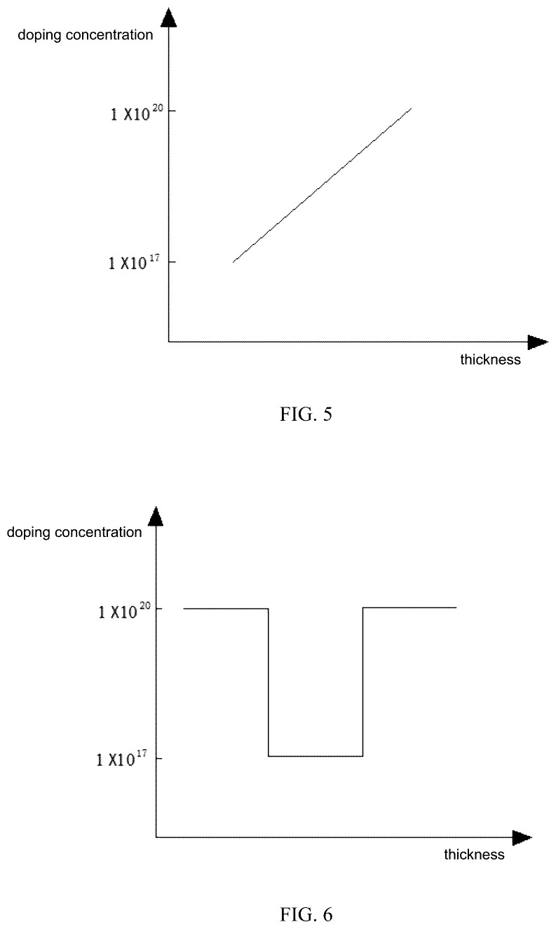

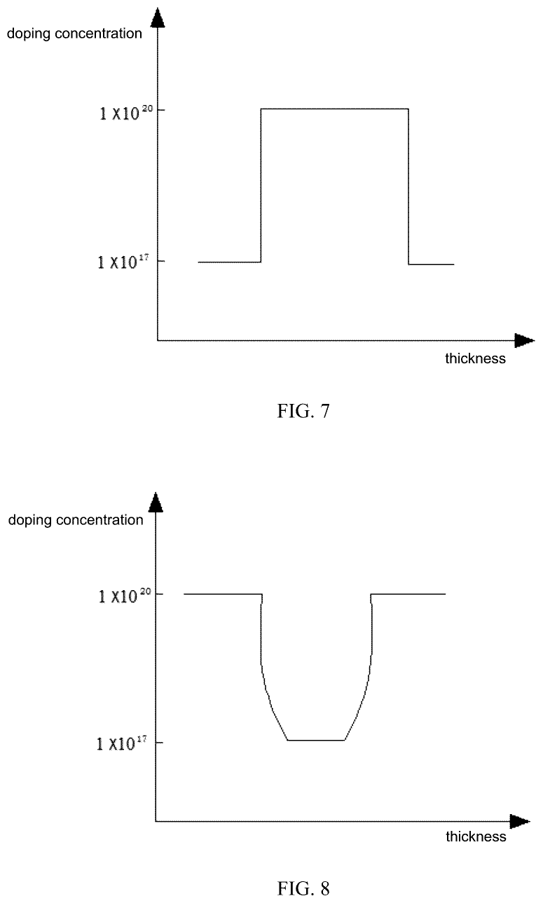

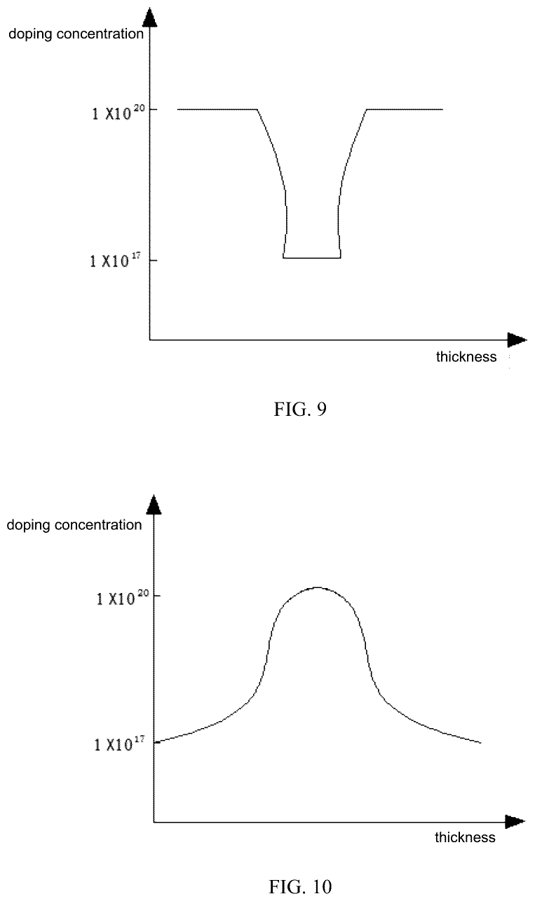

FIGS. 3-10 are schematic diagrams showing the change of the N-type doping concentration with the thickness of the gate elimination layer provided in other examples of the present disclosure, where the abscissa represents the thickness, and the ordinate represents the N-type doping concentration. FIG. 10 shows a gradual doping method. It should be noted that, FIGS. 2-10 are only for illustration and not limitation of the present disclosure.

In some examples, the present disclosure provides an LED chip, and the LED chip includes the semiconductor epitaxial structure of any of the above. Furthermore, the LED chip may include an N-type electrode which is in ohmic contact with the N-type semiconductor layer 140 and a P-type electrode which is in ohmic contact with the P-type semiconductor layer 190.

In the semiconductor epitaxial structure provided by the present disclosure, a gate elimination layer 150 is provided between the N-type semiconductor layer 140 and the active layer 170, and the gate elimination layer 150 includes an N-type doped semiconductor layer. Further, the gate elimination layer 150 includes a non-uniform N-type doped semiconductor layer. In some examples, the N-type doping concentration of the gate elimination layer 150 gradually increases or decreases gradually along the first direction, or changes or varies in a gradient. Thus, excess electrons are released, the electron concentration is effectively increased, the probability of electron tunneling is increased, the crystal quality is improved while the working voltage of the LED is reduced, and the antistatic ability of the LED is improved.

Further, by setting: a shallow well layer is provided between the gate elimination layer 150 and the active layer 170, and the shallow well layer includes several sub-shallow well layers 160 stacked in sequence along the first direction; the lattice constant each sub-shallow well layer 160 increases along the first direction, and the lattice constant of the sub-shallow well layer 160 adjacent to the active layer 170 is lower than the lattice constant of the active layer 170; the energy band of each sub-shallow well layer 160 decreases along the first direction, and the energy band of the sub-shallow well layer 160 adjacent to the active layer 170 is higher than the energy band of the active layer 170. At the same time, each sub-shallow well layer 160 is constituted by alternate cycles of potential barrier layers 161 and potential well layers 162, and the lattice constant of the gate elimination layer 150 is smaller than that of the potential well layer 162 of the first sub-shallow well layer 160 along the first direction. Furthermore, the energy band of the gate elimination layer 150 is greater than the energy band of the potential well layer 162 of the first sub-shallow well layer 160 along the first direction. The V-Pits structure in the active layer 170 can be effectively opened. On the one hand, the density and opening size of the V-Pits structure can be controlled, and the internal quantum efficiency of the active layer 170 can be improved to improve LED characteristics. In addition, through the above settings, effectively inhibit the extension of the V-Pits structure, while improving the radiation recombination efficiency of the active layer 170 (that is, improving the external quantum efficiency), reduce the leakage channel of the LED and improve the electrical performance of the LED. Moreover, through the above settings, it can further release the stress of the active layer 170 and its underlying dislocations.

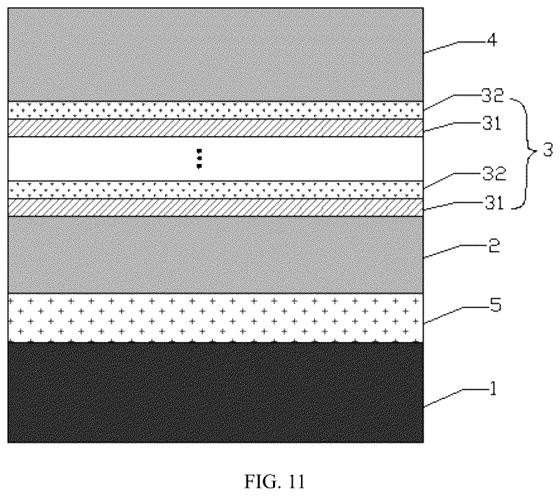

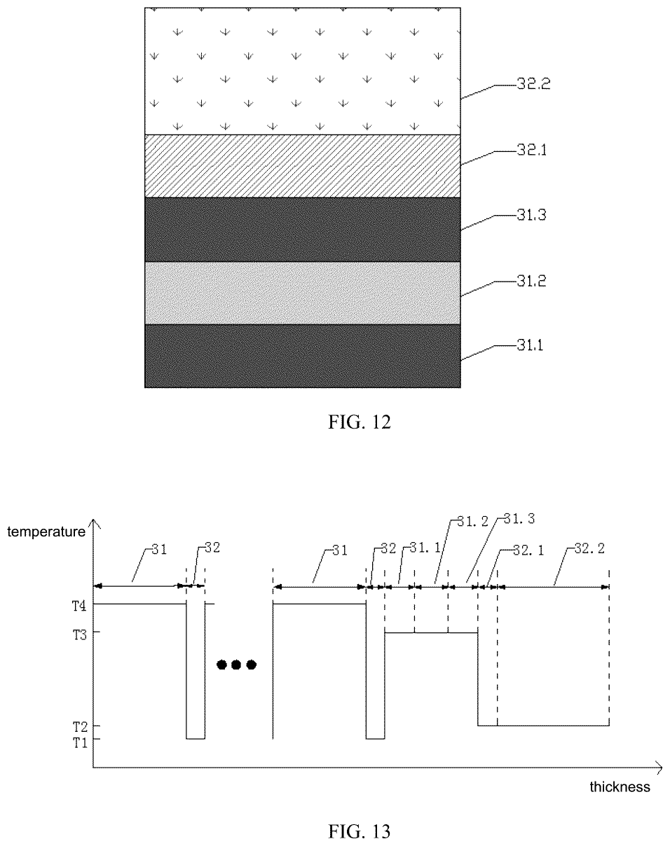

FIGS. 11-12 show another example of a semiconductor epitaxial structure in accordance with the present disclosure. As shown in FIGS. 11 and 12, the semiconductor epitaxial structure includes a substrate 1, an N-type semiconductor layer 2, an active region 3 and a P-type semiconductor layer 4. In some examples, the active region 3 may be in similar structure and correspondingly include the shallow well layer and/or the active layer 7 as shown in FIG. 1. The substrate 1 may be in the same structure as the substrate 110 in FIG. 1, the N-type semiconductor layer 2 may be in the same structure as the N-type semiconductor layer 140, and the P-type semiconductor layer may be in the same structure as the P-type semiconductor layer 190.

As shown in FIG. 11, the active region 3 includes alternately stacked potential barrier layers 31 and potential well layers 32, and a potential well layer 32 close to the P-type semiconductor layer 4 includes an AlₓGa_{y}In_{z}N material layer whose Indium (In) composition gradually decreases along the growth direction, where 0≤x≤1, 0≤y≤1, 0≤z≤0 where the growth direction is perpendicular to the substrate 1 and directed from the substrate 1 to the N-type semiconductor layer.

In some examples, the type of the substrate 1 is not limited in the semiconductor epitaxial structure of this embodiment, for example, the substrate 1 may be but not limited to a sapphire substrate 1, a silicon substrate 1 and the like. In addition, the specific material types of the N-type semiconductor layer 2, the active region 3, and the P-type semiconductor layer 4 may not be limited to the semiconductor epitaxial structure as shown in the figures of the present disclosure. For example, the N-type semiconductor layer 2 may be but not limited to a gallium nitride layer, and correspondingly, the P-type semiconductor layer 4 may be but not limited to a gallium nitride layer.

In some examples, the potential well layer 32 closest to or adjacent to the P-type semiconductor layer 4 is the last potential well layer 32, and the last potential well layer 32 includes AlₓGa_{y}In_{z}N with P-type doping and the In composition gradually decreases along the growth direction.

In some examples, in the potential well layer 32, each In composition value corresponds to a sub-AlₓGa_{y}In_{z}N material layer, and the thickness of each sub-AlₓGa_{y}In_{z}N material layer gradually increases along the growth direction.

In some examples, the last potential well layer 32 includes a first AlGaInN material layer 32.1 and a second AlGaInN material layer 32.2 stacked in sequence along the growth direction, and the In composition of the first AlGaInN material layer 32.1 is greater than that of the second AlGaInN material layer In composition of 32.2. It should be noted that the examples only exemplify two sub-AlₓGa_{y}In_{z}N material layers with different In components. In other examples of the present disclosure, there may be multiple sub-AlₓGa_{y}In_{z}N material layers with different In components, which will not be described in detail here. At the same time, this embodiment does not limit the specific indium composition value of each sub-AlₓGa_{y}In_{z}N material layer, as long as the In is better retained in the active region according to the specific material and its thickness, so as to avoid the subsequent high-temperature growth causing In the phenomenon of a large amount of desorption and escape is sufficient.

In some examples, the thickness of the second AlGaInN material layer 32.2 is 5 times or more than the thickness of the first AlGaInN material layer 32.1.

In some examples, the potential barrier layer 31 closest to the P-type semiconductor layer 4 is the last barrier layer 31, and the last barrier layer 31 includes an AlₐGa_{b}N material layer that is not doped and whose Al composition changes gradually along the growth direction, where 0≤a≤1, 0≤b≤1.

In some examples, the Al composition value decreases gradually from the center (e.g., a central point) of the last barrier layer 31 to both ends. Furthermore, the Al composition value at both ends of the last potential barrier layer 31 can be infinitely close to 0.

In some examples, the last barrier layer 31 includes a first AlGaN material layer 31.1, a second AlGaN material layer 31.2, and a third AlGaN material layer 31.3 stacked in sequence along the growth direction, and Al composition of the second AlGaN material layer 31.2 is on average higher than the first AlGaN material layer 31.1 and/or the third AlGaN material layer 31.3. It should be noted that these examples of the present disclosure only exemplify three sub-AlaGabN material layers with a graded Al composition. In other examples of the present disclosure, there may be multiple sub-AlₓGa_{y}In_{z}N material layers with a graded Al composition, which is not specifically limited here.

In some examples, in the active region 3, except for the potential well layer 32 whose In composition is gradually varied, the components of the other potential well layers 32 are constant and not doped.

In some examples, in the active region 3, except for the last barrier layer 31, the components of the other potential barrier layers 31 are constant and N-type doped.

In some examples, a buffer layer 5 may also be provided between the substrate 1 and the N-type semiconductor layer 2.

The present disclosure also provides a method for manufacturing a semiconductor epitaxial structure as shown in FIGS. 11-12, and the method includes the following steps:

Step S201, providing a substrate 1; and

Step S202, growing an N-type semiconductor layer 2, an active region 3, and a P-type semiconductor layer 4 sequentially on the surface of the substrate 1.

The active region 3 includes alternately stacked potential barrier layers 31 and potential well layers 32, and the potential well layer 32 close to the P-type semiconductor layer 4 includes an AlₓGa_{y}In_{z}N material layer whose In composition gradually decreases along the growth direction, where 0≤x≤1, 0≤≤1, 0≤z≤1. The growth direction is perpendicular to the substrate 1, and is directed from the substrate 1 to the N-type semiconductor layer.

Further, the potential well layer 32 closest to the P-type semiconductor layer 4 is the last potential well layer 32, and the last potential well layer 32 includes a P-type doped AlₓGa_{y}In_{z}N material layer whose In composition gradually decreases along the growth direction. Each In composition value corresponds to a sub-AlₓGa_{y}In_{z}N material layer, and the thickness of each sub-AlₓGa_{y}In_{z}N material layer is gradually thickened along the growth direction.

Further, the potential barrier layer 31 closest to the P-type semiconductor layer 4 is the last barrier layer 31, and the last barrier layer 31 includes an AlₐGa_{b}N material layer that is not doped and whose Al composition gradually changes along the growth direction, where 0≤a≤1, 0≤b≤1. The Al composition value gradually decreases from the center position (e.g., a central point) of the last barrier layer 31 to both ends.

Moreover, in the active region 3, except for the potential well layer 32 whose In composition is gradually changed, the components of the other potential well layers are constant and undoped; except for the last barrier layer 31, the components of the remaining potential well layers are constant and N-type doped.

As shown in FIG. 3, in this embodiment, the growth temperature of the potential well layer 32 with a gradually varied In composition is T2, and the growth temperature of the other potential well layers 32 is T1, where 0≤T2−T1 ≤50° C.

In some examples, the growth temperature of the last potential barrier layer 31 is T3, and the growth temperature of the other potential barrier layers 31 is T4, 0≤T4−T3 ≤100° C.

It should be noted that FIG. 3 is a schematic diagram of the relationship between the growth temperatures of the constituent layers in the active region 3 provided in some examples, which only illustrates the linear change of the growth temperature of the constituent layers in the active region 3. These examples do not limit the specific temperature and its changing trend during the growth process of the potential barrier layer 31, the first AlGaN material layer 31.1, the second AlGaN material layer 31.2, the third AlGaN material layer 31.3, the potential well layer 32, the first AlGaInN material layer 32.1, and the second AlGaInN material layer 32.2, which may be linear or non-linear.

In some examples, the present disclosure also provides an LED chip, including an epitaxial layer, an N-type electrode and a P-type electrode, wherein the epitaxial layer includes any one of the semiconductor epitaxial structures described above.

It can be known from the above technical solutions that the semiconductor epitaxial structure provided by the present disclosure, by setting the potential well layer 32 close to the P-type semiconductor layer 4, includes an AlₓGa_{y}In_{z}N material layer whose In composition gradually decreases along the growth direction, where 0≤x≤1, 0≤y≤1, 0≤z≤1. Further, the last potential well layer 32 along the growth direction includes a P-type doped AlₓGa_{y}In_{z}N material layer whose In composition gradually decreases along the growth direction. A certain amount of holes is stored at the edge of the active region 3, which facilitates the subsequent migration of the holes to the active region 3, thereby improving the recombination efficiency of electrons and holes in the space of the active region 3.

Secondly, by setting the potential well layer 32 close to the P-type semiconductor layer 4 to include an AlₓGa_{y}In_{z}N material layer whose In composition gradually decreases along the growth direction; and each In composition value corresponds to a sub-AlₓGa_{y}In_{z}N material layer, the thickness of the AlₓGa_{y}In_{z}N material layer is gradually thickened along the growth direction; on the one hand, it is beneficial to better retain In in the active region 3, avoiding the phenomenon of a large amount of desorption and escape of In caused by subsequent high-temperature growth; on the other hand, the thickness of the AlxGaylnzN material layer gradually increases along the growth direction, which is also beneficial to improving the hole storage capacity of the active region 3.

Furthermore, the last barrier layer 31 along the growth direction includes an undoped AlₐGa_{b}N material layer whose Al composition gradually changes along the growth direction, where 0≤a≤1, 0≤b≤1; the Al composition value gradually decreases toward both ends along the center position of the last potential barrier layer 31; and except the last potential barrier layer 31, the components of the other potential barrier layers are constant and N-type doped. It can effectively reduce the diffusion of electrons to the P-type semiconductor layer 4 caused by N-type doping in the active region 3.

Furthermore, it can be seen from the above technical solutions that in the semiconductor epitaxial structure provided by the present disclosure, a gate elimination layer is provided between the N-type semiconductor layer and the active layer, and the gate elimination layer includes an N-type doped semiconductor layer. Further, the gate elimination layer includes a non-uniform N-type doped semiconductor layer. Wherein, the N-type doping concentration of the gate elimination layer gradually increases or decreases gradually or changes in a gradient along the first direction; and the highest doping concentration of the gate elimination layer along the first direction is greater than that of the N-type doping concentration of the semiconductor layer. Thus, excess electrons are released, the electron concentration is effectively increased, the probability of electron tunneling is increased, the crystal quality is improved while the working voltage of the LED is reduced, and the antistatic ability of the LED is improved.

Further, by setting: a shallow well layer is provided between the gate elimination layer and the active layer, and the shallow well layer includes several sub-shallow well layers stacked in sequence along the first direction; each of the lattice constant of the sub-shallow well layer increases along the first direction, and the lattice constant of the sub-shallow well layer adjacent to the active layer is lower than the lattice constant of the active layer; each of the sub-shallow well layers of the well layer decreases along the first direction, and the energy band of the sub-shallow well layer adjacent to the active layer is higher than the energy band of the active layer. At the same time, each of the sub-shallow well layers is formed by alternate cycles of potential barriers and potential wells, and the lattice constant of the gate elimination layer is smaller than that of the potential wells of the first sub-shallow well layer along the first direction. constant, the energy band of the gate elimination layer is greater than the energy band of the potential well of the first sub-shallow well layer along the first direction. It can effectively open the V-Pits structure in the active layer. On the one hand, it can control the density and opening size of the V-Pits structure, improve the internal quantum efficiency of the active layer, and improve the LED characteristics; in addition, through the above settings, the effective Inhibit the extension of the V-Pits structure, improve the radiation recombination efficiency of the active layer (that is, increase the external quantum efficiency), reduce the LED leakage channel, and improve the electrical performance of the LED; moreover, through the above settings, the active layer can be further released stress and its underlying dislocations.

It can be seen from the above technical solutions that the method for manufacturing a semiconductor epitaxial structure provided by the present disclosure realizes the above-mentioned beneficial effects of the semiconductor epitaxial structure, and at the same time, its manufacturing process is simple and convenient, and is convenient for production.

It can be seen from the above technical solutions that the LED chip provided by the present disclosure is obtained on the basis of the above-mentioned semiconductor epitaxial structure, so it has the beneficial effect of the above-mentioned semiconductor epitaxial structure, and at the same time, its process is simple and convenient, and it is convenient for production.

What is claimed is:

1. A semiconductor epitaxial structure, comprising:
a substrate, an N-type semiconductor layer, a gate elimination layer, an active layer, and a P-type semiconductor layer,
wherein the N-type semiconductor layer, the gate elimination layer, the active layer, and the P-type semiconductor layer are sequentially stacked on the substrate, and
wherein the gate elimination layer comprises an N-type doped semiconductor layer.

2. The semiconductor epitaxial structure according to claim 1, wherein the gate elimination layer comprises a non-uniform N-type doped semiconductor layer.

3. The semiconductor epitaxial structure according to claim 1, wherein an N-type doping concentration in the gate elimination layer varies in one of following manners:
gradually increasing along a first direction;
gradually decreasing along the first direction; or
varying in a gradient,
wherein a highest N-type doping concentration of the gate elimination layer along the first direction is greater than an N-type doping concentration of the N-type semiconductor layer, and
wherein the first direction is perpendicular to the substrate and from the substrate to the N-type semiconductor layer.

4. The semiconductor epitaxial structure according to claim 1, further comprising:
a shallow well layer that is sandwiched between the gate elimination layer and the active layer,
wherein the shallow well layer comprises a plurality of sub-shallow well layers that are sequentially stacked along a first direction.

5. The semiconductor epitaxial structure according to claim 4, wherein a lattice constant of each sub-shallow well layer increases along the first direction, and a lattice constant of an adjacent sub-shallow layer that is adjacent to the active layer is smaller than a lattice constant of the active layer, and
wherein energy band of each sub-shallow well layer decreases along the first direction, and energy band of the adjacent sub-shallow layer that is adjacent to the active layer is greater than energy band of the active layer.

6. The semiconductor epitaxial structure according to claim 4, wherein each of the plurality of sub-shallow well layers comprises a potential barrier layer and a potential well layer, potential barrier layers and potential well layers are arranged in an alternating manner,
wherein a lattice constant of the gate elimination layer is smaller than a lattice constant of a potential well layer in a first sub-shallow well layer along the first direction, and
wherein energy band of the gate elimination layer is greater than energy band of the potential well layer in the first sub-shallow well layer.

7. The semiconductor epitaxial structure according to claim 6, wherein an adjacent potential well layer that is adjacent to the active layer comprises one or more AlₓGa_{y}In_{z}N material layers, wherein Indium (In) composition gradually decreases along a growth direction in the one or more one or more AlₓGa_{y}In_{z}N material layers, and wherein 0≤x≤1, 0≤y≤1, and 0≤z≤1.

8. The semiconductor epitaxial structure according to claim 7, wherein the adjacent potential well layer is a last potential well layer and the adjacent potential well layer comprises the AlₓGa_{y}In_{z}N material layer with P-type doping.

9. The semiconductor epitaxial structure according to claim 7, wherein each of the one or more AlₓGa_{y}In_{z}N material layers corresponds to an In composition value, and a thickness of each of the one or more AlₓGa_{y}In_{z}N material layers gradually increases along the growth direction.

10. The semiconductor epitaxial structure according to claim 8, wherein the last potential well layer comprises a first AlGaInN material layer and a second AlGaInN layer that are sequentially stacked along the growth direction, and
wherein Indium (In) composition of the first AlGaInN material layer is greater than In composition of the second AlGaInN material layer, or
wherein a thickness of the second AlGaInN material layer is equal to or greater than five times of a thickness of the first AlGaInN material layer.

11. The semiconductor epitaxial structure according to claim 7, wherein an adjacent potential barrier layer is a last potential barrier layer comprising one or more AlₐGa_{b}N material layers with non-doping, wherein Al composition in the one or more AlₐGa_{b}N material layers varies gradually in the growth direction, wherein 0≤a≤1, 0≤b≤1.

12. The semiconductor epitaxial structure according to claim 11, wherein an Al composition value in the last potential barrier layer gradually decreases from a central location to an end of the last potential barrier layer.

13. The semiconductor epitaxial structure according to claim 11, wherein the last potential barrier layer comprises a first AlGaN material layer, a second AlGaN layer, and a third AlGaN layer that are sequentially stacked along the growth direction, and wherein Al composition of the second AlGaN layer is greater than Al composition of the first AlGaN material layer or the third AlGaN material layer.

14. The semiconductor epitaxial structure according to claim 7, wherein all potential well layers other than the adjacent potential well layer are not doped and components in the all potential well layer other than the adjacent potential well layer are constant;
wherein all potential barrier layers other than a last potential barrier layer are N-type doped and components in the all potential barrier layers other than the last potential barrier layer are constant.

15. The semiconductor epitaxial structure according to claim 1, wherein an N-type doping concentration in the gate elimination layer is between 1×10¹⁷ to 1×10²⁰ cm⁻³.

16. The semiconductor epitaxial structure according to claim 1, wherein the gate elimination layer comprises an N-type doped GaN layer, an N-type doped AlGaN layer, an N-type doped AlGaInN layer, an N-type doped GaInN layer, or an N-type doped AlInN layer.

17. The semiconductor epitaxial structure according to claim 1, wherein a number the plurality of sub-shallow well layers is between 1 to 20, including endpoint values.

18. The semiconductor epitaxial structure according to claim 1, wherein a thickness of the gate elimination layer is no greater than 100 nm.

19. A Light-emitting diode (LED) chip, comprising:
a semiconductor epitaxial structure, comprising:
a substrate, an N-type semiconductor layer, a gate elimination layer, an active layer, and a P-type semiconductor layer,
wherein the N-type semiconductor layer, the gate elimination layer, the active layer, and the P-type semiconductor layer are sequentially stacked on the substrate, and
wherein the gate elimination layer comprises an N-type doped semiconductor layer;
a N-type electrode that is in Ohmic contact with the N-type semiconductor layer; and
a P-type electrode that is in Ohmic contact with the P-type semiconductor layer.

20. The LED chip according to claim 19, wherein the semiconductor epitaxial structure further comprises a shallow well layer that is sandwiched between the gate elimination layer and the active layer, wherein the shallow well layer comprises a plurality of sub-shallow well layers that are sequentially stacked along a first direction;
wherein each of the plurality of sub-shallow well layers comprises a potential barrier layer and a potential well layer, potential barrier layers and potential well layers are arranged in an alternating manner; and
wherein an adjacent potential well layer that is adjacent to the active layer comprises one or more AlₓGa_{y}In_{z}N material layers, wherein Indium (In) composition gradually decreases along a growth direction in the one or more one or more AlₓGa_{y}In_{z}N material layers, and wherein 0≤x≤1, 0≤y≤1, and 0≤z≤1.
